(19) United States
(12) Patent Application Publication
(10) Pub. No.: US 2021/0223639 A1
(43) Pub. Date: Jul. 22, 2021

(54) ARRAY SUBSTRATE, DISPLAY DEVICE, AND FABRICATING METHOD THEREOF

(71) Applicants: Hefei BOE Display Technology Co., Ltd., Hefei (CN); BOE TECHNOLOGY GROUP CO., LTD., Beijing (CN)

(72) Inventors: Chunxu ZHANG, Beijing (CN); Yuntian ZHANG, Beijing (CN); Zhonghou WU, Beijing (CN); Peng JIANG, Beijing (CN); Yafei DENG, Beijing (CN); Ke DAI, Beijing (CN)

(73) Assignees: Hefei BOE Display Technology Co., Ltd., Hefei (CN); BOE TECHNOLOGY GROUP CO., LTD., Beijing (CN)

(21) Appl. No.: 16/632,161

(22) PCT Filed: May 29, 2019
(86) PCT No.: PCT/CN2019/089020

§ 371 Date: Jan. 17, 2020

(30) Foreign Application Priority Data
Jan. 2, 2019 (CN) 201910001869.0

(51) Int. Cl. G02F 1/1362; G02F 1/1368; H01L 27/02; H01L 27/12; H01L 29/786

(52) U.S. Cl. CPC G02F 1/136204; G02F 1/1368; H01L 27/127; H01L 27/1222; H01L 29/78696; H01L 27/0274

(57) ABSTRACT

An array substrate is disclosed, the array sul cluding: a pixel display transistor having a first source, a first drain, and a first channel region, the first channel region having a first channel length extending between the first source and the first drain; an antistatic transistor having a second source, a second drain, and a second channel region; and a conductive block in the second channel region between the second source and the second drain; wherein the first channel region and second channel region are patterned regions of a same semiconductor material layer; and the conductive block divides the second channel region into a first sub-channel and a second sub-channel.

### CROSS-REFERENCE TO RELATED APPLICATION

This application is based on and claims priority from Chinese Patent Application No. 201910001869.0, filed on Jan. 2, 2019, the entire contents of which are incorporated herein by reference.

### TECHNICAL FIELD

The present disclosure relates to display technologies, and in particular, relates to an array substrate, a display device, and a fabricating method thereof.

### BACKGROUND

During the operation of a liquid crystal panel, static electricity may be introduced at any time due to various external conditions. Once the static electricity is accumulated in the panel and cannot be released, the panel may be damaged, and the display performance may be degraded. Therefore, it is extremely important to provide an antistatic structure in the display panel.

### SUMMARY

Embodiments of the present disclosure provide an array substrate, a display device, and a fabricating method thereof.

According to a first aspect of the present disclosure, there is provided an array substrate, the array substrate including: a pixel display transistor having a first source, a first drain, and a first channel region, the first channel region having a first channel length extending between the first source and the first drain; an antistatic transistor having a second source, a second drain, and a second channel region; and a conductive block in the second channel region between the second source and the second drain; wherein the first channel region and second channel region are patterned regions of a same semiconductor material layer; and the conductive block divides the second channel region into a first sub-channel and a second sub-channel.

The first sub-channel and the second sub-channel may be in serial arrangement between the second source and the second drain.

The first sub-channel may have a sub-channel length approximately equal to the first channel length.

The second sub-channel may have a sub-channel length approximately equal to the first channel length.

The array substrate may further include a plurality of conductive blocks in the second channel region; wherein the conductive blocks divide the second channel region into a plurality of sub-channels in serial between the second source and the second drain, each sub-channel having a sub-channel length approximately equal to the first channel length.

The first source, the first drain, the second source, and the second drain may be patterned regions of a same conductive layer.

The conductive block may be another patterned region of the same conductive layer.

The first channel region may have a U-shaped channel; and the first channel length may be a minimum distance from the first source to the first drain along the U-shaped channel.

The pixel display transistor may be a transistor of a driving circuit for driving a display pixel.

The pixel display transistor may be within a display area of the array substrate, and the antistatic transistor may be within a non-display area of the array substrate.

The array substrate may include four antistatic transistors connected in serial, the four antistatic transistors including a first antistatic transistor, a second antistatic transistor, a third antistatic transistor, and a fourth antistatic transistor; wherein a source of the first antistatic transistor is connected to a gate of the first antistatic transistor; a drain of the first antistatic transistor is connected to a gate of the second antistatic transistor; the gate of the first antistatic transistor is connected to a source of the second antistatic transistor; a drain of the second antistatic transistor is connected to the gate of the second antistatic transistor and a source of the third antistatic transistor; the gate of the second antistatic transistor is connected to a gate of the third antistatic transistor; the source of the third antistatic transistor is connected to the gate of the third antistatic transistor; a drain of the third antistatic transistor is connected to a gate of the fourth antistatic transistor; the gate of the third antistatic transistor is connected to a source of the fourth antistatic transistor; and a drain of the fourth antistatic transistor is connected to the gate of the fourth antistatic transistor.

According to a second aspect of the present disclosure, there is provided a display device including the array substrate.

According to a third aspect of the present disclosure, there is provided a method of fabricating an array substrate, including: forming a pixel display transistor having a first source, a first drain, and a first channel region, the first channel region having a first channel length extending between the first source and the first drain; forming an antistatic transistor having a second source, a second drain, and a second channel region; and forming a conductive block in the second channel region between the second source and the second drain; wherein the first channel region and second channel region are patterned regions of a same active layer; and the conductive block divides the second channel region into a first sub-channel and a second sub-channel.

The method may further include forming a first conductive layer; and patterning the first conductive layer to form a first gate for the pixel display transistor, and a second gate for the antistatic transistor.

The method may further include forming a semiconductor material layer; and patterning the semiconductor material layer to form the first channel region and the second channel region.

The method may further include forming a second conductive layer; and patterning the second conductive layer to form the first source, the first drain, the second source, the second drain, and the conductive block.

The first sub-channel and the second sub-channel may be in serial arrangement between the second source and the second drain. The first sub-channel may have a sub-channel length approximately equal to the first channel length. The second sub-channel may have a sub-channel length approximately equal to the first channel length.

The method may further include forming a plurality of conductive blocks in the second channel region; wherein the conductive blocks divide the second channel region into a plurality of sub-channels in serial between the second source and the second drain, each sub-channel having a sub-channel length approximately equal to the first channel length.

### BRIEF DESCRIPTION OF DRAWINGS

A more particular description of the embodiments will be rendered by reference to specific embodiments illustrated in the appended drawings. Given that these drawings depict only some embodiments and are not therefore considered to be limiting in scope, the embodiments will be described and explained with additional specificity and details through the use of the accompanying drawings, in which:

FIG. 1 is a plan view showing a pixel display transistor of an array substrate according to an exemplary embodiment;

FIG. 2 is a sectional view of FIG. 1 along line A-A′;

FIG. 3 is a plan view showing an antistatic transistor of the array substrate;

FIG. 4 is a sectional view of FIG. 3 along line B-B′;

FIG. 5 shows steps of forming an antistatic transistor and a pixel display transistor according to an exemplary embodiment;

FIG. 6 is an equivalent circuit diagram of an antistatic structure of an array substrate according to an exemplary embodiment; and

FIG. 7 is a plan view showing an antistatic structure of the array substrate.

### DETAILED DESCRIPTION

The disclosure will be described hereinafter with reference to the accompanying drawings, which illustrate embodiments of the disclosure. The described embodiments are only exemplary embodiments of the present disclosure, but not all embodiments. Other embodiments may be obtained by a person of ordinary skill in the art based on the embodiments of the present disclosure without creative efforts, and are within the scope of the present disclosure.

References throughout the disclosure to “one embodiment”, “an embodiment”, “an example”, “some embodiments”, or similar language mean that a particular feature, structure, or characteristic described in connection with the embodiment is included in at least one embodiment. Thus, appearances of the phrases “in one embodiment”, “in an embodiment”, “in some embodiments”, and similar language throughout the disclosure may, but do not necessarily, all refer to the same embodiment(s), but mean “one or more embodiments”. These may or may not include all the embodiments disclosed.

Unless otherwise defined, technical terms or scientific terms used in the embodiments of the present disclosure should be construed in the ordinary meaning of the person of ordinary skill in the art.

The terms “first”, “second” and similar terms used in the present disclosure do not denote any order, quantity, or importance. They are merely used for references to relevant devices, components, procedural steps, etc. These terms do not imply any spatial or chronological orders, unless expressly specified otherwise. For example, a “first device” and a “second device” may refer to two separately formed devices, or two parts or components of the same device. Similarly, a “first step” of a method or process may be carried or performed after, or simultaneously with, a ‘second step”.

The terms “comprising”, “including”, “having”, and variations thereof mean “including but not limited to”, unless expressly specified otherwise.

An enumerated listing of items does not imply that any or all of the items are mutually exclusive, unless expressly specified otherwise. The terms “a”, “an”, and “the” also refer to “one or more” unless expressly specified otherwise.

The words “connected” or “connection” and the like are not limited to physical or mechanical connections, but may include electrical connections, whether direct or indirect.

For large-sized display products, considering the large load and charging difficulties, a narrow-channel halftone mask is used in the design, and the size of the pixel display transistor in the display area is made as small as possible (i.e. the channel length is close to the exposure accuracy). However, the antistatic structure still utilizes a conventional design of the channel length (i.e. about 2 to 10 times the exposure accuracy) because of its functional requirements. In optics, when the size of the exposure slit approaches the exposure accuracy, a loss of exposure may occur. Therefore, the amount of exposure in the display area is smaller than the amount of exposure in the antistatic structure region, and after the exposure, development and stripping, the photoresist thickness remaining in the channel of the transistor in the display area and that remaining in the channel of the antistatic transistor in the antistatic structure region differ. As a result, the channel of the antistatic transistor in the antistatic structure region may be etched through during an etching process, resulting in failure of the antistatic transistor.

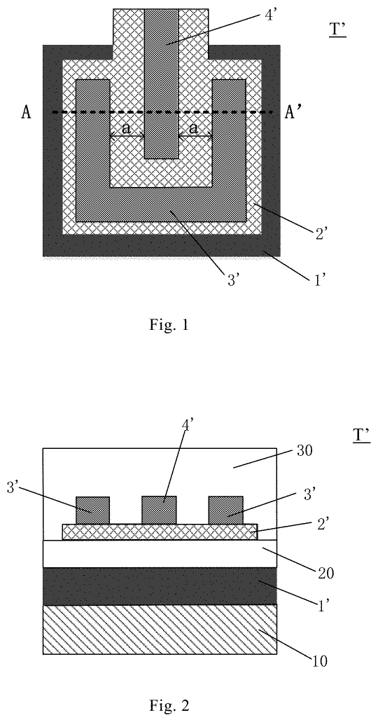

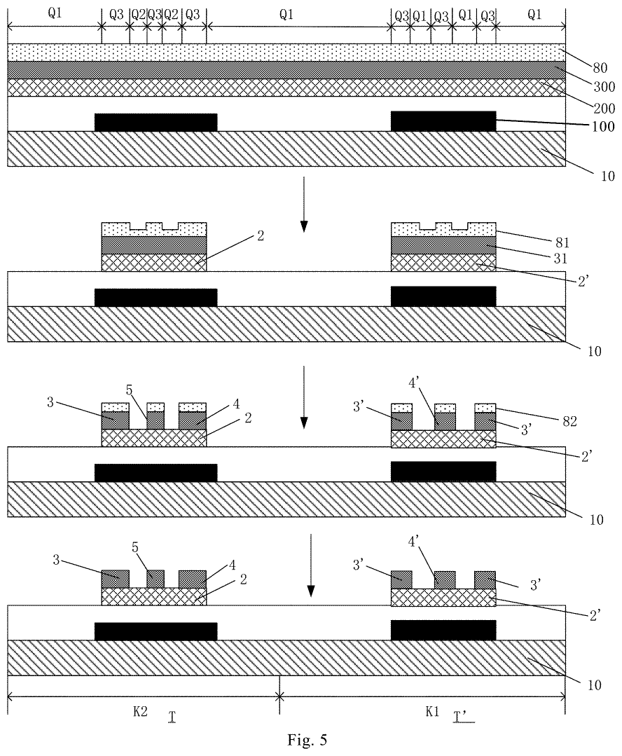

At least one embodiment of the present disclosure provides an array substrate. As shown in FIG. 5, the array substrate includes a display area Kl, a peripheral area surrounding the display area K1, and an antistatic area K2 located in the peripheral area. An antistatic structure is disposed in the antistatic area K2 and a pixel structure is disposed in the display area K1, the antistatic structure including an antistatic transistor T, and the pixel structure including a pixel display transistor T′. That is, the pixel display transistor T′ is within a display area of the array substrate; and the antistatic transistor T is within a non-display area of the array substrate. An active layer 2 of the antistatic transistor T and an active layer 2′ of the pixel display transistor T′ are disposed in a same layer and are made of a same material; a source 3 and a drain 4 of the antistatic transistor T, and a source 3′ and a drain 4′ of the pixel display transistor T′ are disposed in a same layer and are made of a same material; and an conductive block 5 is disposed between the source 3 and the drain 4 of the antistatic transistor T and in the same layer as the source 3 and the drain 4, and is made of the same material as the source 3 and the drain 4 of the antistatic transistor T. As shown in FIGS. 1, 3 and 5, the distance b between the source 3 of the antistatic transistor T and the conductive block 5, and the distance b between the drain 4 of the antistatic transistor T and the conductive block 5 are substantially the same as the channel length a of a channel region of the active layer 2′ of the pixel display transistor T′.

That is, the array substrate according to an embodiment of the present disclosure includes a pixel display transistor T′ having a first source 3′, a first drain 4′, and a first channel region, the first channel region having a first channel length a extending between the first source 3′ and the first drain 4′; an antistatic transistor T having a second source 3, a second drain 4, and a second channel region; and a conductive block 5 between the second source 3 and the second drain 4 in the second channel region; wherein the first channel region and second channel region are patterned regions of a same active layer 2 (2′); and the conductive block 5 divides the second channel region into a first sub-channel C1 and a second sub-channel C2.

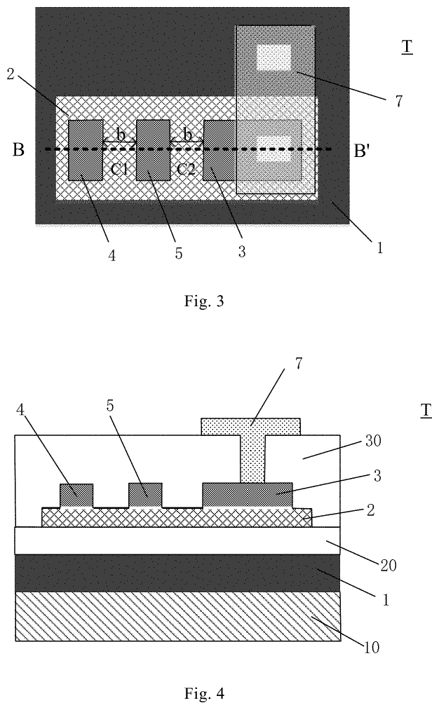

The pixel display transistor may be a transistor of a driving circuit for driving a display pixel. For example, the source 3′ and the drain 4′ of the pixel display transistor T′ define a U-shaped channel region (i.e. a first channel region) of the active layer 2′ having a channel length a as illustrated in FIG. 1, which may be a minimum distance from the source 3′ to the drain 4′ along the U-shaped channel. For example, as illustrated in FIG. 3, the conductive block 5 is formed between the source 3 and the drain 4 of the antistatic transistor T, defining a first portion (the first sub-channel) and a second portion (the second sub-channel) of a channel region (i.e. a second channel region) of the active layer 2 of the antistatic transistor T; and the first and the second portions are respectively a portion of the channel region of the active layer 2 of the antistatic transistor between the source 3 and the conductive block 5 and a portion of the channel region of the active layer 2 of the antistatic transistor between the drain 4 and the conductive block 5, each having a length b. The channel length a of the U-shaped channel region, and the sub-channel lengths b of the first portion and the second portion of the channel region of the antistatic transistor may be the same, that is, the length a and the length b as shown in FIGS. 1 and 3 are substantially equal. In this way, exposure amount is the same when forming the channel region of the antistatic transistor and the channel region of the pixel display transistor, and thus the channel region of the antistatic transistor is prevented from being etched through to the utmost extent while the active layer 2, the source 3 and the drain 4 of the antistatic transistor T, and the active layer 2′, the source 3′ and the drain 4′ of the pixel display transistor T′ are formed by etching, avoiding a problem of antistatic transistor failure.

For example, the conductive block 5 forms an auxiliary electrode, such that the antistatic transistor T is effectively equivalent to two serially connected transistors. As shown in FIG. 3, the first sub-channel C1 and the second sub-channel C2 of the channel region of the antistatic transistor T are in serial arrangement between the source 3 and the drain 4 of the antistatic transistor T; and the first sub-channel C1 and the second sub-channel C2 may have a sub-channel length approximately equal to the first channel length of the pixel display transistor T′.

In an embodiment, a plurality of conductive blocks between the source 3 and the drain 4 of the antistatic transistor T may be provided, which divides the channel region of the antistatic transistor T into a plurality of sub-channels in serial between the source 3 and the drain 4, and each sub-channel may have a sub-channel length approximately equal to the first channel length.

In an embodiment, the active layer 2 of the antistatic transistor T is disposed in the same layer as the active layer 2′ of the pixel display transistor T′, and the materials of the two are the same; the source 3 and the drain 4 of the antistatic transistor T are disposed in the same layer as the source 3′ and the drain 4′ of the pixel display transistor T′ and the materials are the same; and the conductive block 5 is disposed between the source 3 and the drain 4 of the antistatic transistor T and in the same layer, and is made of the same material as the source 3 and the drain 4. That is, the source 3′ and the drain 4′ of the pixel display transistor T′, and the source 3 and the drain 4 of the antistatic transistor T are patterned regions of a same conductive layer, for example, a metal film; and the conductive block 5 is another patterned region of the same conductive layer. With such arrangement, the active layer 2, the source 3 and the drain 4 of the antistatic transistor T, and the active layer 2′, the source 3′ and the drain 4′ of the pixel display transistor T′ can be fabricated by one patterning process, and the conductive block 5 can also be formed between the source 3 and the drain 4 of the antistatic transistor T in the same patterning process.

The distance between the source 3 of the antistatic transistor T and the conductive block 5, and the distance between the drain 4 of the antistatic transistor T and the conductive block 5 may substantially equal to the channel length of the channel region of the active layer 2′ of the pixel display transistor T′. With such arrangement, in the use of halftone mask or grayscale mask, a photoresist layer above the source/drain metal film remaining between the source 3 of the antistatic transistor and the conductive block 5 and between the drain 4 of the antistatic transistor and the conductive block 5, after exposure, developing, and stripping, has a thickness which is substantially the same as that of a photoresist layer on the channel region of the active layer 2′ of the pixel display transistor, thereby effectively preventing the channel region of the antistatic transistor from being etched through, while the active layer 2, and the source 3 and the drain 4 of the antistatic transistor, and the active layer 2′, the source 3′ and the drain 4′ of the pixel display transistor are formed by etching.

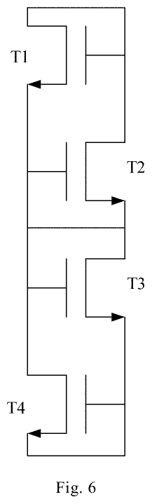

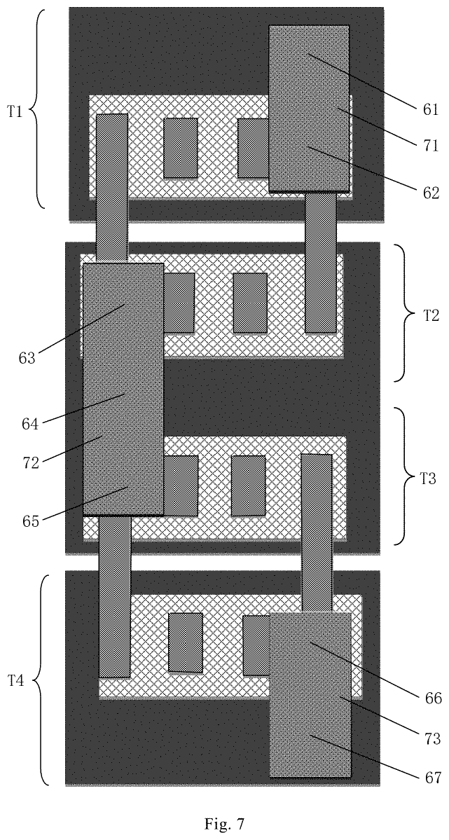

In an embodiment, an exemplary antistatic structure is provided as shown in FIGS. 6 and 7, which includes four antistatic transistors connected in serial; and the four antistatic transistors are a first antistatic transistor T1, a second antistatic transistor T2, a third antistatic transistor T3, and a fourth antistatic transistor T4, respectively. The source 3 of the first antistatic transistor T1 is connected to its gate 1; the drain 4 of the first antistatic transistor T1 is connected to the gate 1 of the second antistatic transistor T2; the gate 1 of the first antistatic transistor T1 is connected to the source 3 of the second antistatic transistor T2; the drain 4 of the second antistatic transistor T2 is connected to its gate 1, and is also connected to the source 3 of the third antistatic transistor T3; the gate 1 of the second antistatic transistor T2 is connected to the gate 1 of the third antistatic transistor T3; the source 3 of the third antistatic transistor T3 is connected to its gate 1; the drain 4 of the third antistatic transistor T3 is connected to the gate 1 of the fourth antistatic transistor T4; the gate 1 of the third antistatic transistor T3 is connected to the source 3 of the fourth antistatic transistor T4; and the drain 4 of the fourth antistatic transistor T4 is connected to its gate 1. Of course, the antistatic structure is not limited to the above, and may be other known structures.

The material of the active layer 2 (2′) of the antistatic transistors and the pixel display transistor in the embodiment includes any one of amorphous silicon, polycrystalline silicon, and hydrogenated amorphous silicon. Of course, the material of the active layer 2 is not limited to these.

At least one embodiment of the present disclosure further provides a display device including the above array substrate. Since the display device in the embodiment includes the above array substrate, its performance is better.

The display device may be a liquid crystal display device, such as a liquid crystal panel, a mobile phone, a tablet computer, a television, a monitor, a notebook computer, a digital photo frame, a navigator, or any product or component having a display function.

According to an embodiment of the present disclosure, a method of fabricating an array substrate is provided, the method including: forming a pixel display transistor T′ having a first source 3′, a first drain 4′, and a first channel region, the first channel region having a first channel length extending between the first source 3′ and the first drain 4′; forming an antistatic transistor T having a second source 3, a second drain 4, and a second channel region, the second channel region having a second channel length extending between the second source 3 and the second drain 4; and forming a conductive block 5 between the second source 3 and the second drain 4 in the second channel region; wherein the first channel region and second channel region are patterned regions of a same active layer 2 (2′); and the conductive block 5 divides the second channel region into a first sub-channel C1 and a second sub-channel C2.

As shown in FIG. 5, the fabrication method of the array substrate includes: forming an antistatic structure in the antistatic area K2 and forming a pixel structure in the display area K1; wherein the step of forming the antistatic structure including forming an antistatic transistor T and the step of forming the pixel structure includes forming a pixel display transistor T′. In particular, with reference to FIGS. 1, 3 and 5, the active layer 2′, the source 3′ and the drain 4′ of the pixel display transistor T′ are formed by one patterning process together with the active layer 2, the source 3 and the drain 4 of the antistatic transistor T, and the conductive block 5 between the source 3 and the drain 4 of the antistatic transistor.

The steps of forming the active layer 2, the source 3 and the drain 4 of the antistatic transistor T, the active layer 2′, the source 3′ and the drain 4′ of the pixel display transistor T′, and the conductive block 5, i.e. the steps of forming the pixel display transistor T′, the antistatic transistor T and the conductive block 5, will be specifically described below.

As shown in FIG. 5, first, a semiconductor material layer (i.e. an active layer) 200 and a source/drain metal film 300 (i.e. a second conductive layer 300) are sequentially deposited on a substrate 10, and a photoresist layer 80 is coated on the source/drain metal film 300. Next, a halftone mask or a grayscale mask is applied such that the part of the photoresist layer 80 corresponding to the source 3′ and the drain 4′ of the pixel display transistor T′, the source 3 and the drain 4 of the antistatic transistor, and the auxiliary electrode 5 or the conductive block 5 is not exposed (i.e., the non-exposure region Q3 of the mask); the part of the photoresist layer 80 corresponding to the region between the source 3 and the conductive block 5 of the antistatic transistor T, the region between the drain 4 and the conductive block 5 of the antistatic transistor T, and the channel region of the pixel display transistor T′ is half-exposed (i.e., the half-exposure region Q2 of the mask); and the remaining part of the photoresist layer 80 is completely exposed (i.e., the fully exposure region Q1 of the mask). Thereafter, the photoresist material corresponding to the fully exposure region, and a certain thickness of the photoresist material corresponding to the half-exposure region (the remaining thickness is a first thickness that is less than the total thickness of the photoresist layer) is removed to obtain a first photoresist pattern 81; an etching process is used to remove the source/drain metal material and the semiconductor material corresponding to the fully exposure region to obtain a first source/drain pattern 31; and then, the first photoresist pattern 81 may be partially removed, i.e. reducing its thickness, to obtain a second photoresist pattern 82, and the source/drain metal material corresponding to the half-exposure region is removed, thereby forming the active layer 2, the source 3 and the drain 4 of the antistatic transistor T, the active layer 2′, the source 3′ and the drain 4′ of the pixel display transistor T′, and the conductive block 5. The second photoresist pattern 82 may then be removed. In the method of fabricating the array substrate according to the embodiment, after forming the semiconductor material layer and the source/drain metal film, the semiconductor material layer is patterned to form the channel region of the active layer 2 of the antistatic transistor T and the channel region of the active layer 2′ of the pixel display transistor T′, and the source/drain metal film is patterned to form the source 3, the drain 4, and the conductive block 5 of the antistatic transistor T, and the source 3′ and the drain 4′ of the pixel display transistor T′. That is, the active layer 2, the source 3 and the drain 4 of the antistatic transistor T are fabricated by one patterning process with the active layer 2′, the source 3′ and the drain 4′ of the pixel display transistor T′. In the same patterning process, the conductive block 5 is also formed between the source 3 and the drain 4 of the antistatic transistor T. The distance between the source 3 of the antistatic transistor and the conductive block 5, and the distance between the drain 4 of the antistatic transistor T and the conductive block 5 are substantially the same as the channel length of the channel region of the active layer 2′ of the pixel display transistor T′.

In some embodiments, a single patterning process using half-tone mask may be applied to the source/drain metal film 300 and the semiconductor material layer 200 to simultaneously form the pixel display transistor T′ and the antistatic transistor T with the conductive block 5. In some other embodiments, two separate patterning processes may be applied to the source/drain metal film 300 and the semiconductor material layer 200.

With the use of the halftone mask or grayscale mask, the photoresist layer above the source/drain metal film remaining between the source 3 of the antistatic transistor and the conductive block 5 and between the drain 4 of the antistatic transistor and the conductive block 5, after exposure, developing, and stripping, may have a thickness which is substantially the same as that of the photoresist layer on the channel region of the active layer 2′ of the pixel display transistor T′, thereby effectively preventing the channel region of the antistatic transistor from being etched through (this causes antistatic transistor failure), while the active layer 2, and the source 3 and the drain 4 of the antistatic transistor T, and the active layer 2′, the source 3′ and the drain 4′ of the pixel display transistor T′ are formed by etching, and avoiding the problem of antistatic transistor failure.

The source 3′ and the drain 4′ of the pixel display transistor T′ define a U-shaped channel region of the active layer 2′ having a channel length a as illustrated in FIG. 1; the conductive block 5 is formed between the source 3 and the drain 4 of the antistatic transistor T, defining a first portion (the first sub-channel) and a second portion (the second sub-channel) of a channel region of the active layer 2 of the antistatic transistor T; the first and the second portions are a portion of the channel region of the active layer 2 of the antistatic transistor between the source 3 and the conductive block 5 and a portion of the channel region of the active layer 2 of the antistatic transistor between the drain 4 and the conductive block 5 respectively, each having a length b as illustrated in FIG. 3. The channel length a of the U-shaped channel region, and the sub-channel lengths b of the first portion and the second portion of the channel region of the active layer 2 of the antistatic transistor are the same, that is, the length a and the length b as shown in FIGS. 1 and 3 are substantially equal. In this way, the exposure amount is the same when forming the channel region of the antistatic transistor and the channel region of the pixel display transistor, and thus the channel region of the antistatic transistor is prevented from being etched though to the utmost extent while the active layer 2, and the source 3 and the drain 4 of the antistatic transistor T, and the active layer 2′, the source 3′ and the drain 4′ of the pixel display transistor T′ are formed by etching, avoiding the problem of antistatic transistor failure.

It should be noted that only a part of the display area K1 and the antistatic area K2 in the array substrate is shown in FIG. 5, and FIG. 5 only illustrates the specific process flow of fabricating the active layer 2, the source 3 and the drain 4 of the antistatic transistor T, the conductive block 5, and the active layer 2′, the source 3′, and the drain 4′ of the pixel display transistor T′. As shown in FIGS. 2 and 4, and taking the antistatic transistor and the pixel display transistor both being bottom gate type thin film transistors as an example, before forming the active layer of the antistatic transistor and the pixel display transistor, the method further includes: forming a gate 1′ of the pixel display transistor T′ and a gate 1 of the antistatic transistor T on the substrate 10 by one patterning process, i.e. forming a first conductive layer 100 and patterning the first conductive layer 100 to form a first gate 1′ for the pixel display transistor, and a second gate 1 for the antistatic transistor; and then forming a gate insulating layer 20. It should also be noted here that the source 3 of the antistatic transistor is connected to its gate 1. Therefore, as shown in FIGS. 3 and 4, after forming the source 3 and the drain 4 of the antistatic transistor T, an interlayer insulating layer 30 is formed. A first via hole is etched at a position of the interlayer insulating layer 30 corresponding to the source 3 of the antistatic transistor, and a second via hole is etched through the interlayer insulating layer 30 and the gate insulating layer 20 to the gate 1 of the antistatic transistor. Thereafter, a connecting portion 7 is formed by a patterning process, and the connecting portion 7 covers the two via holes to electrically connect the source 3 of the antistatic transistor with its gate 1.

The material of the first conductive layer 100 is one of molybdenum (Mo), molybdenum-niobium alloy (MoNb), aluminum (Al), aluminum-niobium alloy (AlNd), titanium (Ti) and copper (Cu), or a single layer or multilayer laminate formed by a plurality of the abovementioned materials. The material is preferably a single layer or a multilayer film composed of Mo, Al and/or alloys containing Mo and/or Al.

An exemplary method for fabricating an array substrate is disclosed with reference to FIGS. 1-7. The array substrate includes: an antistatic area and a display area; and an antistatic structure is formed in the antistatic area, and a pixel structure is disposed in the display area. In the embodiment, the antistatic structure includes four antistatic transistors connected in serial, and the pixel structure includes a pixel display transistor. Of course, the antistatic structure is not limited to such an arrangement in which four antistatic transistors are connected in serial, and the pixel unit is not limited to including a pixel display transistor. The method of fabricating the array substrate in the embodiment includes the following steps.

Step 1: on the substrate 10, forming respective gates 1 of a first antistatic transistor T1, a second antistatic transistor T2, a third antistatic transistor T3, and a fourth antistatic transistor T4 of each antistatic structure disposed in the antistatic area, and a gate 1′ of a pixel display transistor of a pixel structure disposed in the display area by a patterning process; wherein the second antistatic transistor T2 and the third antistatic transistor T3 use a common gate 1.

In this step, the substrate 10 is made of a transparent material such as glass and is pre-cleaned. Specifically, a gate metal film (i.e. a first conductive layer 100) is deposited on the substrate 10 by means of a plasma enhanced chemical vapor deposition (PECVD) method, a low pressure chemical vapor deposition (LPCVD) method, an atmospheric pressure chemical vapor deposition (APCVD) method, or an electron cyclotron resonance chemical vapor deposition (ECR-CVD) method, and a photoresist is formed on the gate metal film. Then, after exposure by a mask, development and etching, the respective gates 1 (1′) of the transistors are formed.

The material of the gate metal film is one of molybdenum (Mo), molybdenum-niobium alloy (MoNb), aluminum (Al), aluminum-niobium alloy (AlNd), titanium (Ti) and copper (Cu), or a single layer or multilayer laminate formed by a plurality of the abovementioned materials. The material is preferably a single layer or a multilayer film composed of Mo, Al and/or alloys containing Mo and/or Al.

Step 2: on the substrate 10 on which the above step is completed, forming a gate insulating layer 20.

In this step, the gate insulating layer is formed on the substrate 10 on which the above step is completed by plasma enhanced chemical vapor deposition, low pressure chemical vapor deposition, atmospheric pressure chemical vapor deposition, electron cyclotron resonance chemical vapor deposition, or sputtering.

The material of the gate insulating layer 20 may be silicon oxide (SiOx), silicon nitride (SiNx), germanium oxide (HfOx), silicon oxynitride (SiON), aluminum oxide (AlOx), or a multilayer film composed of two or three of these materials.

Step 3: on the substrate 10 on which the above steps are completed, forming respective active layers 2, sources 3, drains 4 of all four antistatic transistors, and a conductive block 5 between the source 3 and the drain 4 of each antistatic transistor by one patterning process; wherein the source 3 of the first antistatic transistor T1 and the source 3 of the second antistatic transistor T2 are integrally formed or integrated; the drain 4 of the first antistatic transistor T1 and the drain 4 of the second antistatic transistor T2 are integrally formed; the source 3 of the third antistatic transistor T3 and the source 3 of the fourth antistatic transistor T4 are integrally formed; and the drain 4 of the third antistatic transistor T3 and the drain 4 of the fourth antistatic transistor T4 are integrally formed.

In this step, first, a semiconductor material (i.e. an active layer) 200 is formed by plasma enhanced chemical vapor deposition or low pressure chemical vapor deposition, followed by forming a source/drain metal film (i.e. a second conductive layer 300) by plasma enhanced chemical vapor deposition, low pressure chemical vapor deposition, atmospheric pressure chemical vapor deposition, electron cyclotron resonance chemical vapor deposition or sputtering. Then, a photoresist layer is formed on the source/drain metal film, and finally, a halftone mask or a grayscale mask is used such that the part of the photoresist layer corresponding to the source 3 and the drain 4 of the pixel display transistor, the source 3 and the drain 4 of each antistatic transistor, and each conductive block 5 is not exposed (i.e., the non-exposure region of the mask); the part of the photoresist layer corresponding to the region between the source 3 of each antistatic transistor and the corresponding conductive block 5, the region between the drain 4 of each antistatic transistor and the corresponding conductive block 5, and the channel region of the pixel display transistor is half-exposed (i.e., the half-exposure region of the mask); and the remaining part of the photoresist layer is completely exposed (i.e., the fully exposure region of the mask). Thereafter, the photoresist material corresponding to the fully exposure region, and a certain thickness of the photoresist material corresponding to the half-exposure region (the remaining thickness is a first thickness that is less than the total thickness of the photoresist layer) is removed; an etching process is used to remove the source/drain metal material and the semiconductor material corresponding to the fully exposure region; and then, the photoresist of the first thickness is removed and the source/drain metal material corresponding to the half-exposure region is removed, thereby forming the active layer 2, the source 3 and the drain 4 of each antistatic transistor, the active layer 2′, the source 3′ and the drain 4′ of the pixel display transistor, and each conductive block 5. The source 3 of the first antistatic transistor T1 and the source 3 of the second antistatic transistor T2 are integrally formed or integrated; the drain 4 of the first antistatic transistor T1 and the drain 4 of the second antistatic transistor T2 are integrally formed; the source 3 of the third antistatic transistor T3 and the source 3 of the fourth antistatic transistor T4 are integrally formed; and the drain 4 of the third antistatic transistor T3 and the drain 4 of the fourth antistatic transistor T4 are integrally formed.

The semiconductor material is any one of amorphous silicon, polycrystalline silicon, and hydrogenated amorphous silicon.

The material of the source/drain metal film is one of molybdenum (Mo), molybdenum-niobium alloy (MoNb), aluminum (Al), aluminum-niobium alloy (AlNd), titanium (Ti) and copper (Cu), or a single layer or multilayer laminate formed by a plurality of the abovementioned materials. The material is preferably a single layer or a multilayer film composed of Mo, Al and/or alloys containing Mo and/or Al.

Step 4: forming an interlayer insulating layer 30 on the substrate 10 on which the above steps are completed, and forming a first via hole 61 though the interlayer insulating layer 30 and the gate insulating layer 20 at a position corresponding to the gate 1 of the first antistatic transistor T1, a second via hole 62 though the interlayer insulating layer 30 at a position corresponding to the source 3 of the first antistatic transistor T1, a third via hole 63 through the interlayer insulating layer 30 at a position corresponding to the drain 4 of the second antistatic transistor T2, a fourth via hole 64 through the gate insulating layer 20 and the interlayer insulating layer 30 at a position corresponding to the gates of the second antistatic transistor T2 and the third antistatic transistor T3, a fifth via hole 65 through the interlayer insulating layer 30 at a position corresponding to the source 3 of the third antistatic transistor T3, a sixth via hole 66 through the interlayer insulating layer 30 at a position corresponding to the drain 4 of the fourth antistatic transistor T4, a seventh via hole 67 through the interlayer insulating layer 30 and the gate insulating layer 20 at a position corresponding to the gate 1 of the fourth antistatic transistor T4.

The material of the interlayer insulating layer 30 may be silicon oxide (SiOx), silicon nitride (SiNx), germanium oxide (HfOx), silicon oxynitride (SiON), aluminum oxide (AlOx), or a composite film composed of two or three of these materials.

Step 5: on the substrate 10 on which the above steps are completed, forming, by a patterning process, a first connecting portion 71 corresponding to the positions of the first via hole 61 and the second via hole 62, a second connecting portion 72 corresponding to the positions of the third via hole 63, the fourth via hole 64 and the fifth via hole 65, and a third connecting portion 73 corresponding to the positions of the sixth via hole 66 and the seventh via hole 67; wherein the first connecting portion 71 connects the source 3 of the first antistatic transistor T1, the gate 1 of the first antistatic transistor T1, and the source 3 of the second antistatic transistor together T2; the second connecting portion 72 connects the drain 4 of the second antistatic transistor T2, the gate 1 of the second antistatic transistor T2, the source 3 of the third antistatic transistor T3 and the gate 1 of the third antistatic transistor T3; the third connecting portion 73 connects the drain 4 of the third antistatic transistor T3, the drain 4 of the fourth antistatic transistor T4 and the gate 1 of the fourth antistatic transistor T4.

The material of the first connecting portion 71, the second connecting portion 72, and the third connecting portion 73 may be a transparent conductive material, such as indium tin oxide (ITO).

In the method of fabricating the array substrate according to the embodiment, the active layer 2, the source 3 and the drain 4 of each antistatic transistor are fabricated by one patterning process with the active layer 2′, the source 3′ and the drain 4′ of the pixel display transistor. At the same time, a conductive block 5 is also formed between the source 3 and the drain 4 of each antistatic transistor. The distance between the source 3 of each antistatic transistor and the corresponding conductive block 5, and the distance between the drain 4 of each antistatic transistor and the corresponding conductive block 5 may be substantially the same as the channel length of the channel region of the active layer 2′ of the pixel display transistor. With the usage of the halftone mask or grayscale mask, the photoresist layer above the source/drain metal film remaining between the source 3 of each antistatic transistor and the corresponding conductive block 5 and between the drain 4 of each antistatic transistor and the corresponding conductive block 5, after exposure, developing, and stripping, has a thickness which is substantially the same as that of the photoresist layer on the channel region of the active layer 2′ of the pixel display transistor, thereby effectively preventing the channel region of the antistatic transistor from being etched through, while the active layer 2, and the source 3 and the drain 4 of the antistatic transistor, and the active layer 2′, the source 3′ and the drain 4′ of the pixel display transistor is formed by etching, and avoiding the problem of antistatic transistor failure.

It should be noted that, in the above fabrication method, the fabrication method is described by taking the antistatic transistor and the pixel display transistor being of a bottom gate type as an example. In practice, the antistatic transistor and the pixel display transistor may be a top gate type thin film transistor as well; and during fabrication of such antistatic transistor and pixel display transistor, the only difference, compared with the above described fabrication method, is that the active layer 2(2′) is formed before by the gate 1(1′), and thus the details are not repeated here.

Various embodiments and/or examples are disclosed to provide exemplary and explanatory information to enable a person of ordinary skill in the art to put the disclosure into practice. Features or components disclosed with reference to one embodiment or example are also applicable to all embodiments or examples unless specifically indicated otherwise.

Although the disclosure is described in combination with specific embodiments, it is to be understood by the person skilled in the art that many changes and modifications may be made and equivalent replacements may be made to the components without departing from a scope of the disclosure. Embodiments may be practiced in other specific forms. The described embodiments are to be considered in all respects only as illustrative and not restrictive.

1. An array substrate, comprising:
a pixel display transistor having a first source, a first drain, and a first channel region, the first channel region having a first channel length extending between the first source and the first drain;
an antistatic transistor having a second source, a second drain, and a second channel region; and
a conductive block in the second channel region between the second source and the second drain;
wherein the first channel region and second channel region are patterned regions of a same semiconductor material layer; and
the conductive block divides the second channel region into a first sub-channel and a second sub-channel.

2. The array substrate according to claim 1, wherein the first sub-channel and the second sub-channel are in serial arrangement between the second source and the second drain.

3. The array substrate according to claim 1, wherein the first sub-channel has a sub-channel length approximately equal to the first channel length.

4. The array substrate according to claim 3, wherein the second sub-channel has a sub-channel length approximately equal to the first channel length.

5. The array substrate according to claim 3, further comprising a plurality of conductive blocks in the second channel region; wherein the conductive blocks divide the second channel region into a plurality of sub-channels in serial between the second source and the second drain, each sub-channel having a sub-channel length approximately equal to the first channel length.

6. The array substrate according to claim 1, wherein the first source, the first drain, the second source, and the second drain are patterned regions of a same conductive layer.

7. The array substrate according to claim 6, wherein the conductive block is another patterned region of the same conductive layer.

8. The array substrate according to claim 1, wherein the first channel region has a U-shaped channel; and the first channel length is a minimum distance from the first source to the first drain along the U-shaped channel.

9. The array substrate according to claim 1, wherein the pixel display transistor is a transistor of a driving circuit for driving a display pixel.

10. The array substrate according to claim 1, wherein the pixel display transistor is within a display area of the array substrate, and the antistatic transistor is within a non-display area of the array substrate.

11. The array substrate according to claim 1, wherein the array substrate comprises four antistatic transistors connected in serial, the four antistatic transistors comprising a first antistatic transistor, a second antistatic transistor, a third antistatic transistor, and a fourth antistatic transistor;
wherein a source of the first antistatic transistor is connected to a gate of the first antistatic transistor; a drain of the first antistatic transistor is connected to a gate of the second antistatic transistor; the gate of the first antistatic transistor is connected to a source of the second antistatic transistor; a drain of the second antistatic transistor is connected to the gate of the second antistatic transistor and a source of the third antistatic transistor; the gate of the second antistatic transistor is connected to a gate of the third antistatic transistor; the source of the third antistatic transistor is connected to the gate of the third antistatic transistor; a drain of the third antistatic transistor is connected to a gate of the fourth antistatic transistor; the gate of the third antistatic transistor is connected to a source of the fourth antistatic transistor; and a drain of the fourth antistatic transistor is connected to the gate of the fourth antistatic transistor.

12. A display device, comprising an array substrate, wherein the array substrate comprises:
a pixel display transistor having a first source, a first drain, and a first channel region, the first channel region having a first channel length extending between the first source and the first drain;
an antistatic transistor having a second source, a second drain, and a second channel region; and
a conductive block in the second channel region between the second source and the second drain;
wherein the first channel region and second channel region are patterned regions of a same semiconductor material layer; and
the conductive block divides the second channel region into a first sub-channel and a second sub-channel.

13. A method of fabricating an array substrate, comprising:
forming a pixel display transistor having a first source, a first drain, and a first channel region, the first channel region having a first channel length extending between the first source and the first drain;
forming an antistatic transistor having a second source, a second drain, and a second channel region; and
forming a conductive block in the second channel region between the second source and the second drain;
wherein the first channel region and second channel region are patterned regions of a same active layer; and
the conductive block divides the second channel region into a first sub-channel and a second sub-channel.

14. The method according to claim 13, further comprising:
forming a first conductive layer; and
patterning the first conductive layer to form a first gate for the pixel display transistor, and a second gate for the antistatic transistor.

15. The method according to claim 13, further comprising:
forming a semiconductor material layer; and
patterning the semiconductor material layer to form the first channel region and the second channel region.

16. The method according to claim 13, further comprising:
forming a second conductive layer; and
patterning the second conductive layer to form the first source, the first drain, the second source, the second drain, and the conductive block.

17. The method according to claim 13, wherein the first sub-channel and the second sub-channel are in serial arrangement between the second source and the second drain.

18. The method according to claim 13, wherein the first sub-channel has a sub-channel length approximately equal to the first channel length.

19. The method according to claim 18, wherein the second sub-channel has a sub-channel length approximately equal to the first channel length.

20. The method according to claim 13, further comprising:
forming a plurality of conductive blocks in the second channel region;
wherein the conductive blocks divide the second channel region into a plurality of sub-channels in serial between the second source and the second drain, each sub-channel having a sub-channel length approximately equal to the first channel length.
